(19) United States
(12) Patent Application Publication
(10) Pub. No.: US 2005/0212181 A1
(43) Pub. Date: Sep. 29, 2005

(54) Thermoforming of ink jet printed media for the decoration of soft grained automotive interior components

(76) Inventors: Gregg S. Evans, Windsor (CA); Andrew L. Dargavell, Oxford, MI (US)

Correspondence Address: DYKEMA GOSSETT PLLC, FRANKLIN SQUARE, THIRD FLOOR WEST, 1300 I STREET, NW, WASHINGTON, DC, 20005, US

(21) Appl. No.: 11/043,231

(22) Filed: Jan. 27, 2005

Related U.S. Application Data
(60) Provisional application No. 60/556,879, filed on Mar. 29, 2004.

(51) Int. Cl. B29C 51/10; B29D 9/00; C04B 41/00; B29D 29/00; H01J 37/30; B29C 45/00; B29C 47/00; B29C 43/02; B29D 24/00; B29D 29/06; B29D 29/08; B29C 49/00; B29C 51/00

(52) U.S. Cl. 264/485; 264/132; 264/553; 264/510

(57) ABSTRACT

A method and apparatus for thermoforming of ink jet printed media for decoration of automotive interior components. The method includes controlling an ink jet printer head for dispersed ink application onto a thermoplastic sheet and selecting a graphic pattern for application onto the thermoplastic sheet. The method further includes applying the graphic pattern onto the thermoplastic sheet by means of the ink jet printer head to thereby form a decorated thermoplastic sheet, the graphic pattern including a dispersed ink pattern which includes a plurality of ink drops having spacing therebetween, with the spacing defining a plurality of inter-ink drop zones. The method yet further includes vacuum forming the decorated thermoplastic sheet into a desired shape, and applying the vacuum formed decorated thermoplastic sheet to an automotive interior component structural foundation. The invention also provides a method of associating, selecting and applying a graphic pattern onto a thermoformed automotive interior component.

### CROSS-REFERENCE TO RELATED APPLICATIONS

This application claims the benefit of U.S. Provisional Patent Application No. 60/556,879 filed Mar. 29, 2004, hereby incorporated by reference in its entirety.

### BACKGROUND OF INVENTION

a. Field of Invention

The invention relates generally to the manufacture of automotive interior “show” (visible surface) components, and, more particularly to a method and apparatus for producing high quality large area graphic patterns on three-dimensional soft grained automotive interior components, such as automotive instrument panels, doors and the like.

b. Description of Related Art

In the art, there presently exist a variety of methods for printing graphics on the interior components of automobiles. Known methods include, for example, methods such as the pad printing, silk screening and hydrographics methods. Other graphics technologies used on automotive interior components are limited to trim plate applications (these plates appear typically above the glove box and below the instrument panel's top deck, as well as around instruments).

Technologies such as hydrographics are typically used on trim plates to produce graphics on the three-dimensional plastic surface. While adequate for trim plate applications, the gloss level produced by the hydrographics technique is too high to be used on the areas intended to be covered by the present invention (i.e. the somewhat soft section of “the top deck” of the instrument panel where glossy finishes may cause reflections in the windshield).

Pad printing typically involves an image to be transferred first being etched into a printing plate commonly referred to as a cliche. Once mounted in the machine, the cliche is flooded with ink, and its surface then doctored clean, leaving ink only in the image area. As solvents evaporate from the image area, the ink's ability to adhere to the silicone transfer pad increases. The pad is then positioned directly over the cliche, pressed onto it to pick up the ink, and then lifted away. The physical changes that take place in the ink during flooding and wiping account for its ability to leave the recessed engraving in favor of the pad. After the pad has lifted away from the cliche to its complete vertical height, there is a delay before the ink is deposited on the substrate. During this stage, the ink has just enough adhesion to stick to the pad. The ink on the pad surface once again undergoes physical changes such that solvents evaporate from the outer ink layer that is exposed to the atmosphere, making it tackier and more viscous. The pad is then pressed down onto the substrate, conforming to its shape and depositing the ink in the desired location. Even though the pad compresses considerably during this step, the contoured pad is designed to roll away from the substrate surface rather than press against it flatly. The pad lifts away from the substrate and assumes its original shape again, leaving all of the ink on the substrate, with the ink undergoing physical changes during the head stroke and losing its affinity for the pad. When the pad is pressed onto the substrate, the adhesion between the ink and substrate is greater than the adhesion between the ink and pad, resulting in a virtually complete deposit of the ink. This leaves the pad clean and ready for the next print cycle.

One key drawback of the aforementioned pad printing technology is in the quality and size of the images. For example, typical images produced by the pad printing method are of relatively poor quality (i.e. poor resolution due to limitations in image production control), and are limited to relatively small areas (i.e. within a 4″ diameter range). Moreover, images produced by pad printing can be produced on surfaces having a minimal sweep change and are therefore closer to two-dimensional surfaces. The look produced is bolder than would be suitable for the top surface of an instrument panel (the surface having such image produced thereon might reflect in the windshield), and the image is typically ragged.

Yet further, the aforementioned silk screening method traditionally involves the use of a frame over which a piece of fabric or material is tightly stretched, thus forming a screen. A thin sheet of plastic is placed over the screen and includes holes formed in a pattern resembling the final desired image. With the back of the fabric or material placed on a flat surface, the screen is pressed onto the fabric and material, and thereafter coated with thick ink using a sponge and the like such that ink flows through the screen holes onto the stretched material.

As is readily evident, the final image or pattern formed using silk screening is generally of a low quality (i.e. poor resolution due to limitations in image production control) especially along the edges of the pattern, and is therefore not readily acceptable for printing graphics on the interior or exterior structural components of automobiles. The image produced is also bolder than would be desirable on the top deck of an instrument panel or an automobile door interior surface.

Recently, attempts have been made to print high quality graphics on the interior components of automobiles. For example, U.S. patent application Publication No. 2003/0041962 to Johnson, discloses a process for manufacturing three-dimensionally shaped polymeric sheets and laminates with color-matched digitally printed full color ink jet images. For the process disclosed in Johnson, a flexible thermoformable polymeric baseweb is placed in an ink jet printer and a solvent-based (non-aqueous) digital printing ink is applied directly to the baseweb to form a decorative pattern in multiple colors. The finished product is then thermoformed or injection molded into a three-dimensional shape.

The aforementioned process disclosed in Johnson is however limited to automotive dashboard subcomponents (such as trim plates and bezels), rather than the automotive instrument panel itself (the main grained or textured plastic component running the full width of the vehicle). For example, as discussed in paragraph 28 of Johnson, the objective of the process disclosed in Johnson is to improve upon the gravure printing method, which has a long history in the decoration of trim plates and bezels, as opposed to printing on the main automotive instrument panel due to the surface roughness of surface which has never been decorated with a multiplicity of colored material in a production vehicle. Johnson also illustrates the surface being printed as being flat, as opposed to printing on grained sheets which become the outer surface of an automotive instrument panel. As also discussed in paragraph 28 of Johnson, Johnson refers to thermoforming and/or injection molding the printed sheets to a finished three-dimensional shape, as is standard for trim plates. Thus the aforementioned processes disclosed by Johnson would be inapplicable to an automotive instrument panel itself due to the grained or textured surface thereof, as well as the additional steps needed to form an automotive instrument panel, which require further processes such as the formed sheet continuing on to a urethane foaming process, and bonding of the form to the structural foundation in such a way to pad the surface for tactile reasons.

Other drawbacks in the prior art include the type and fullness of images displayed on a given surface. For example, whereas the prior art, such as Johnson, discloses the printing of “color-matched” or “full color” images (as is typical on trim plates), there exists a need for improved image printing control for printing of images such as simulated shading (i.e. darkened areas of the surface). For such simulated shading, the image may portray shading to hint at three-dimensional details (in particular the shadowing which would appear with a much more deeply grained surface), or to break-up the monochrome appearance of large plastic surfaces (very lightly toned areas, appearing like marbling or faux finishing effects seen on household walls), thereby adding a subtle richness to the look of a component.

Yet further, other drawbacks in the prior art include the consistency of images displayed on a given surface. For example, one drawback with prior art thermoforming techniques is that the image is often distorted or damaged during the thermoforming process. While such prior art thermoforming techniques, as disclosed by Johnson, are not an issue on normally flat trim plate components, these techniques are a major problem when applied to the very three dimensional panels they fit into. This drawback exists due to the flat/continuous nature of the ink layer forming the image, whereby the image layer is damaged due to flexing and/or heating of the substrate material during the thermoforming process. Yet another drawback with prior art thermoforming techniques exists in the use of solvent based inks, which typically require the use of a top protective coating layer to protect the ink from fading or the image from being damaged due to repeated regular wear and tear type of contact with the image surface. For typical instrument panel and door interior surface applications, the use of a top protective coating layer is generally undesirable due to its highly reflective properties, as well as the ergonomic, wear and peeling problems which would readily prohibit the use of such coating layers. There thus exists a need for an image forming and instrument panel thermoforming technique which prevents or minimizes image distortion or damage during the thermoforming process, and further does not require the use of a top protective coating layer for protecting the image from fading or becoming damaged.

It would therefore be of benefit to provide a graphics formation system for facilitating graphic decoration over an entire component surface, with no limitation on the size or versatility of geometry covered. It would also be of benefit to provide a graphics formation system which would be applicable to high speed and/or high volume production of automotive components which have high performance and wear requirements, as well as a system which would permit repeatable application of paint, at a high resolution permitting full tone control to produce ghost (watermark) images onto a component without limitation on the complexity of the final printed image.

### SUMMARY OF INVENTION

The invention solves the problems and overcomes the drawbacks and deficiencies of prior art graphics formation systems by providing a method and apparatus for producing high quality large area graphic patterns on three-dimensional automotive interior components, such as automotive instrument panels, doors and the like.

The present invention thus provides a method of thermoforming of ink jet printed media for decoration of soft grained automotive interior components, excluding hard trim plates. The method may include controlling an ink jet printer head for dispersed ink application onto a thermoplastic sheet, and selecting a predetermined graphic pattern for application onto the thermoplastic sheet. The method may further include applying the predetermined graphic pattern onto the thermoplastic sheet by means of the ink jet printer head to thereby form a decorated thermoplastic sheet, the predetermined graphic pattern including a dispersed ink pattern which includes a plurality of ink drops having spacing between adjacent ink drops, with the spacing defining a plurality of inter-ink drop zones. The method may yet further include vacuum forming the decorated thermoplastic sheet into a desired shape, stretching the decorated thermoplastic sheet during the vacuum forming such that during stretching, the graphic pattern is stretched due to stretching of the inter-ink drop zones, and applying the vacuum formed decorated thermoplastic sheet to an automotive interior component structural foundation using a curing foarn.

For the method described above, the automotive interior component may be an instrument panel and/or a door set having the vacuum formed decorated thermoplastic sheet applied to the structural foundation thereof for thereby forming a soft grained decorated automotive interior component. The graphic pattern on the vacuum formed decorated thermoplastic sheet may be applicable to flat, contoured and/or grained surfaces of the thermoplastic sheet. The ink jet printer head may be a piezoelectric printer head, and utilize the very hard durable (as opposed to the prior art's use of the softer solvent based inks) ultraviolet cured inks, and preferably low gloss ultraviolet cured inks, such that the graphic pattern meets automotive performance criteria, without a protective top clear coat. The graphic pattern may include a plurality of subtle changes in the surface tone of the thermoplastic sheet by using low contrast ink and plastic colors in faint patterns. The vacuum forming process may be a negative vacuum forming process.

The invention further provides a method of thermoforming of ink jet printed media for decoration of automotive interior components. The method may include controlling an ink jet printer head for dispersed ink application onto a thermoplastic sheet, and selecting a predetermined graphic pattern for application onto the thermoplastic sheet. The method may further include applying the predetermined graphic pattern onto the thermoplastic sheet by means of the ink jet printer head to thereby form a decorated thermoplastic sheet, the predetermined graphic pattern including a dispersed ink pattern which includes a plurality of ink drops having spacing therebetween, with the spacing defining a plurality of inter-ink drop zones. The method may yet further include vacuum forming the decorated thermoplastic sheet into a desired shape, and applying the vacuum formed decorated thermoplastic sheet to an automotive interior component structural foundation.

For the method described above, the method may include stretching the decorated thermoplastic sheet during vacuum forming such that during stretching, the graphic pattern is stretched due to stretching of the inter-ink drop zones. The automotive interior component may be an instrument panel and/or a door set having the vacuum formed decorated thermoplastic sheet applied to the structural foundation thereof for thereby forming a decorated automotive interior component. The graphic pattern on the vacuum formed decorated thermoplastic sheet may be applicable to flat, contoured and/or grained surfaces of the thermoplastic sheet. The selected graphic pattern may be applied to soft grained sections of the automotive interior component. The graphic pattern may include a plurality of subtle changes in the surface tone of the thermoplastic sheet by using low contrast ink and plastic colors in faint patterns, The vacuum forming process may be a negative vacuum forming process.

The invention yet further provides an apparatus for thermoforming of ink jet printed media for decoration of automotive interior components. The apparatus may include a controller for controlling an ink jet printer head for dispersed ink application onto a thermoplastic sheet. The apparatus may further include a predetermined graphic pattern being applied onto the thermoplastic sheet by means of the ink jet printer head to thereby form a decorated thermoplastic sheet, the predetermined graphic pattern including a dispersed ink pattern which includes a plurality of ink drops having spacing therebetween, with the spacing defining inter-ink drop zones. The apparatus may also include a vacuum forming apparatus for forming the thermoplastic sheet into a desired shape.

For the apparatus described above, the thermoplastic sheet may be stretched during vacuum forming such that during stretching, the graphic pattern is stretched due to stretching of the inter-ink drop zones. The vacuum formed decorated thermoplastic sheet may be applied to an automotive interior component structural foundation, the automotive interior component being an instrument panel and/or a door set. The graphic pattern on the vacuum formed decorated thermoplastic sheet may be applicable to flat, contoured and/or grained surfaces of the thermoplastic sheet. The ink jet printer head may be a piezoelectric printer head, and utilize ultraviolet cured inks, and preferably low gloss ultraviolet cured inks, such that the graphic pattern meets automotive performance criteria, without a protective top clear coat. The selected graphic pattern may be applied to soft grained sections of the automotive interior component. The graphic pattern may include a plurality of subtle changes in the surface tone of the thermoplastic sheet by using low contrast ink and plastic colors in faint patterns. The vacuum forming apparatus may be a negative vacuum forming apparatus.

The invention also provides a method of associating, selecting and applying a graphic pattern onto a thermoformed automotive interior component. The method may include associating a graphic pattern with a general territory of sale of an automobile, a general category of the automobile, and/or a targeted consumer category related to the automobile. The method may also include selecting an associated graphic pattern for application onto a thermoplastic sheet for forming the automotive interior component, and controlling an ink jet printer head for dispersed ink application onto the thermoplastic sheet. The method may further include applying the predetermined graphic pattern onto the thermoplastic sheet by means of the ink jet printer head to thereby form a decorated thermoplastic sheet, the predetermined graphic pattern including a dispersed ink pattern which includes a plurality of ink drops having spacing therebetween, with the spacing defining a plurality of inter-ink drop zones. The method may yet further include vacuum forming the decorated thermoplastic sheet into a desired shape, and applying the vacuum formed decorated thermoplastic sheet to an automotive interior component structural foundation.

For the method described above, the method may also include stretching the decorated thermoplastic sheet during vacuum forming such that during stretching, the graphic pattern is stretched due to stretching of the inter-ink drop zones. The automotive interior component may be an instrument panel and/or a door set having the vacuum formed decorated thermoplastic sheet applied to the structural foundation thereof for thereby forming a decorated automotive interior component. The graphic pattern on the vacuum formed decorated thermoplastic sheet may be applicable to flat, contoured and/or grained surfaces of the thermoplastic sheet. The ink jet printer head may be a piezoelectric printer head, and utilize ultraviolet cured inks, and preferably low gloss ultraviolet cured inks, such that the graphic pattern meets automotive performance criteria, without a protective top clear coat. The selected graphic pattern may be applied to soft grained sections of the automotive interior component. The graphic pattern may simulate shading for imitating three-dimensional details of a surface of the automotive interior component. The graphic pattern may include a plurality of subtle changes in the surface tone of the thermoplastic sheet by using low contrast ink and plastic colors in faint patterns. The vacuum forming process may be a negative vacuum forming process.

Additional features, advantages, and embodiments of the invention may be set forth or apparent from consideration of the following detailed description, drawings, and claims. Moreover, it is to be understood that both the foregoing summary of the invention and the following detailed description are exemplary and intended to provide further explanation without limiting the scope of the invention as claimed.

### BRIEF DESCRIPTION OF THE DRAWINGS

The accompanying drawings, which are included to provide a further understanding of the invention and are incorporated in and constitute a part of this specification, illustrate preferred embodiments of the invention and together with the detail description serve to explain the principles of the invention. In the drawings:

FIG. 1 is an illustrative block diagram of a graphics formation method according to the present invention including sheet vacuum forming and industrial ink jet printing;

FIG. 2 is an illustrative view of a graphic pattern printed onto an automotive instrument panel by means of the graphics formation method according to the present invention;

FIG. 3 is an enlarged view of the graphic pattern of FIG. 2, illustrating the dispersed ink application of a graphics pattern according to the present invention;

FIG. 4 is a schematic cross-section illustrating a dispersed ink graphic pattern on a rough grained surface, according to the present invention;

FIG. 5 is an illustration of a printing head utilized with a printing system of the graphics formation method according to the present invention;

FIGS. 6(a) and 6(b) are illustrations of the thickness deformation mode and the sliding deformation mode (shear mode), respectively for the piezoelectric element of the printing system according to the present invention;

FIGS. 7(a)-7(d) are schematics for illustrating operation of a printing head according to the present invention when voltage is applied to the piezoelectric walls of the printer head channels, according to the present invention;

FIG. 8 is a flow-chart which illustrates the various steps required for the graphics formation method according to the present invention; and

FIGS. 9(a)-9(c) are illustrative views of additional graphic patterns printed onto an automotive instrument panel by means of the graphics formation method according to the present invention; (JEEP being a registered Trademark of DaimlerChrysler for FIGS. 9(b) and NISSAN being a registered Trademark of Nissan Motor Co., Ltd. for 9(c).

### DETAILED DESCRIPTION OF THE PREFERRED EMBODIMENT

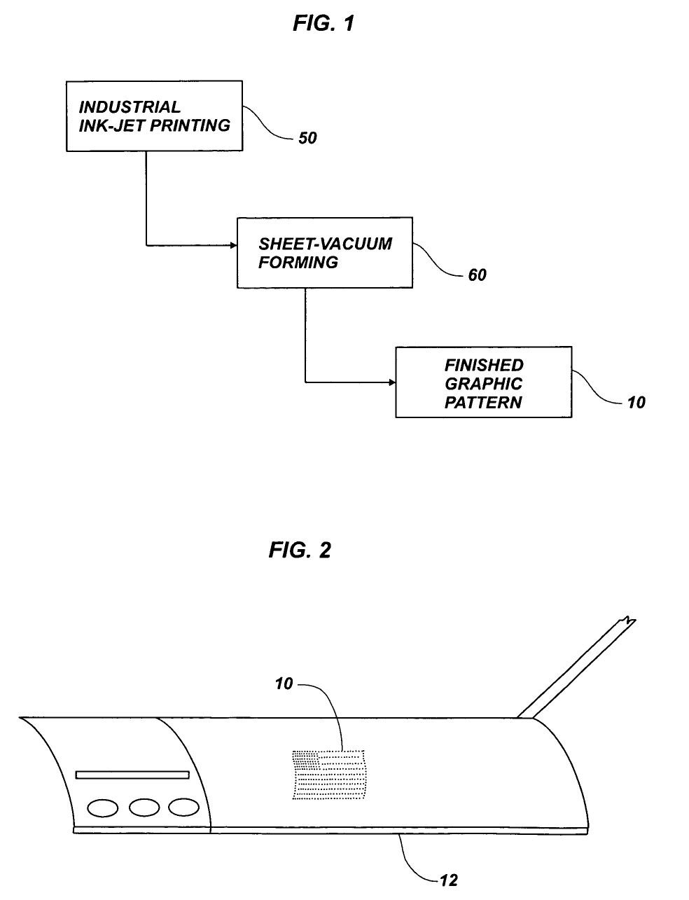

Referring now to the drawings wherein like reference numerals designate corresponding parts throughout the several views, FIGS. 1-9 illustrate a graphics formation method according to the present invention.

As described in greater detail below and illustrated in FIGS. 1 and 2, the graphics formation method according to the present invention generally involves the integration of industrial ink jet printing (generally designated as system/process 50), using a specialized drop pattern, to produce large area graphic effects such as graphic pattern 10 (see FIG. 2) on automotive components such as automotive instrument panel 12, and sheet vacuum forming (generally designated as system/process 60). As also discussed in detail below, proposed patterns according to the graphics formation method of the present invention may include more realistic grain patterns, logos, graphics such as flags and the like, nature images, as well as geometric patterns, such as pattern 10, and any of a variety of patterns which could be produced in near photo quality.

Graphic pattern 10 according to the present invention may be applicable to the soft sections of a variety of automotive grained or textured components, such as automotive dashboard parts which include soft grained vacuum formed sections of the automotive instrument panel itself (the main plastic component, running the full width of the vehicle which is grained or textured), or the soft grained vacuum formed sections of doors and the like. Additionally, graphic pattern 10 may also be applicable to the flat as well as the contoured (three-dimensional) or grained surfaces of the instrument panel.

The graphics formation method according to the present invention, discussed in greater detail below, generally enables the printing of simulated shading (darkened areas of the surface), using black (or very dark) inks. For printing on flat or minimally contoured surfaces, the simulated shading may be used to hint at three-dimensional details (in particular the shadowing which would appear with a much more deeply grained surface). Alternatively, the simulated shading may be used to break-up the monochrome appearance of large plastic surfaces (very lightly toned areas, appearing like marbling or faux finishing effects seen on household walls), thus adding a subtle richness to the look of a surface.

Industrial ink jet printing system 50 utilized with the graphics formation method according to the present invention will now be described in detail with reference to FIGS. 1 and 5-7.

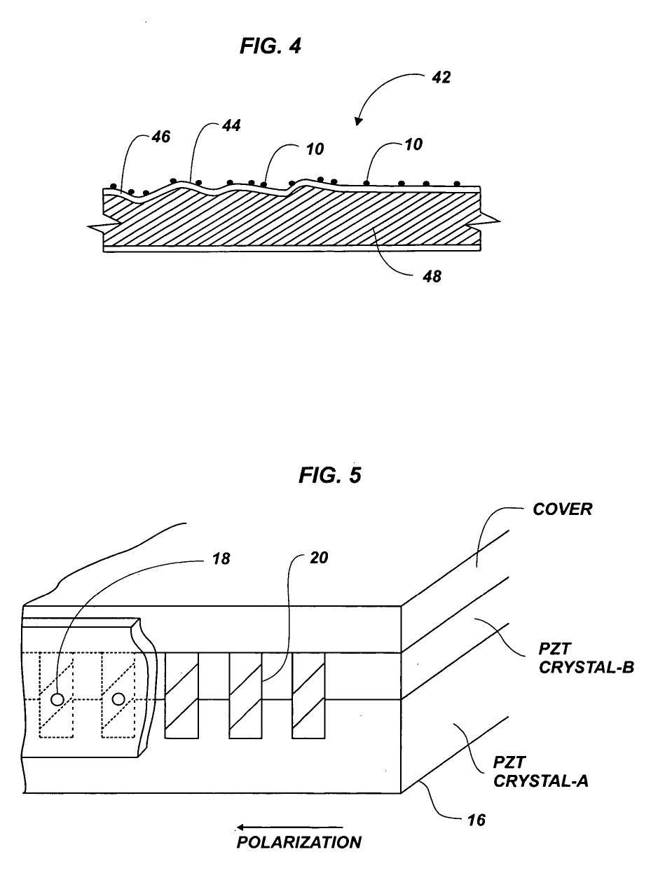

Referring to FIG. 5, industrial ink jet printing system 50 according to the present invention generally includes one or more piezoelectric (PZT) printer heads 16 having a plurality of printing nozzles 18 disposed at the end of printing channels 20. Printer head 16 may operate by producing fine drops of ink through printing nozzles 18 having a diameter of up to 50 microns.

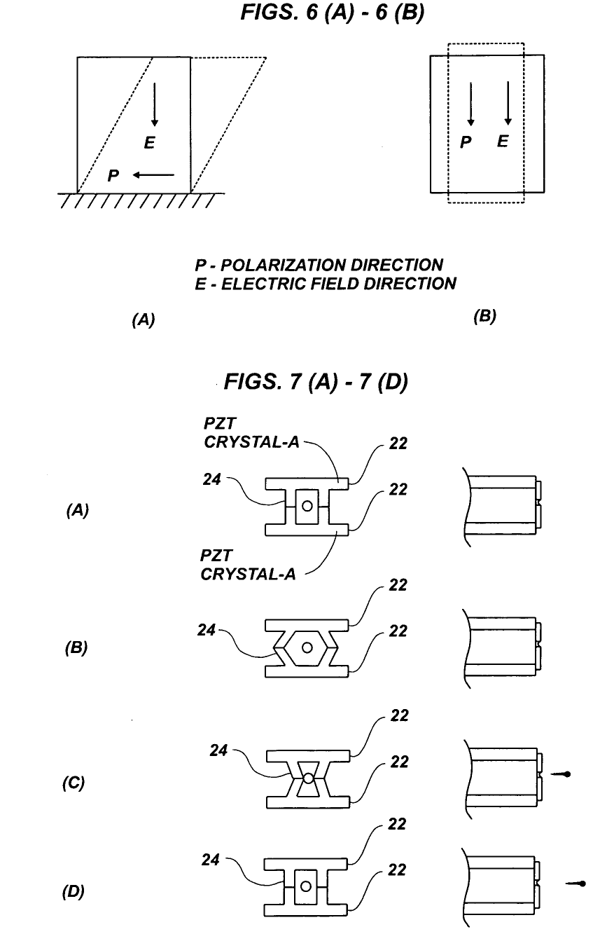

Specifically, referring to FIGS. 6(a) and 6(b), printer head 16 may operate by means of deformation of PZT elements 22, either on the basis of the thickness deformation mode shown in FIG. 6(b), or the sliding deformation mode (shear mode) shown in FIG. 6(a). The thickness deformation mode illustrated in FIG. 6(b) is generated by applying an electric field in the same direction as the polarization direction of the PZT element. The sliding deformation mode illustrated in FIG. 6(a) is generated by applying an electric field perpendicular to the polarization direction of the PZT element.

Referring to FIGS. 5 and 7(a)-7(d), the operation principle of printing channels 20 for printer head 16 according to the present invention will now be described in detail, so as to set forth the basis for the dispersed printing of graphic pattern 10 according to the present invention. Specifically, printing channels 20 may include a small slot created by two PZT crystal plates/elements 22 which are bonded together. When voltage is applied to PZT walls 24 of PZT crystal plates 22 on both sides of printing channels 20, shear mode deformation occurs in both walls, and ink drops are delivered from the printing channels. For example, FIG. 7(a) illustrates the standby mode when no voltage is applied to PZT walls 24. When a positive voltage are applied to PZT walls 24, as shown in FIG. 7(b), an electric field is generated and the PZT walls open. When a negative voltage is applied to PZT walls 24, as shown in FIG. 7(c), a reverse electric field is generated, which makes PZT walls 24 curve in the closing direction, delivering ink drops. Upon removal of voltage, PZT walls 24 are returned to the initial status illustrated in FIGS. 7(a) and 7(d).

Based upon the aforementioned operational principle of printer head 16, the exemplary printer head illustrated in FIG. 5 may include as many as 512 or more printing channels 20, such that when an electrical field is applied to the PZT walls of printing channels 20, the walls of the channels become deformed and eject the ink through printing nozzles 18 at the end of each channel. The ejection of ink droplets through printing nozzles 18 enables tiny individual droplets of ink to travel towards the thermoplastic sheet for forming the required graphic pattern 10, having a dispersed ink pattern, as described below for the graphics formation method according to the present invention.

Referring to FIG. 2, graphic pattern 10 according to the present invention may generally include the use of hard inks, such as ultraviolet cured inks, and preferably low gloss ultraviolet cured inks. In order to apply ink onto the surface of an instrument panel 12, printer head 16 may be configured to spray hot ink (i.e. at approximately 70° C.) in a thin layer over the thermoplastic sheet placed over the instrument panel surface. Once sprayed, the ink generally becomes viscous (i.e. tooth-paste like), and can thereafter be UV cured at a separate location to avoid UV damage to printer head 16.

Printing inks which may be utilized for the aforementioned industrial ink jet printing system according to the present invention include, for example, Aellora Digital (located at Keene, NH) hybrid inks, which are suitable for use with, amongst other materials, thermoplastic and vinyl materials, and which include a low gloss for application on the soft sections of automotive instrument panels, doors and the like, and further, Xaar (located at Cambridge, United Kingdom) or Triangle Digital (located at San Leandro, Calif.) inks.

The use of ultraviolet cured inks for the present invention, as compared to the use of solvent based inks as with the prior art, is sufficient to meet the performance criteria for automotive interior components, with regard to wear and resistance to solvents, without the addition of a protective top coat. The aforementioned graphics formation method according to the present invention thus enables the creation of prints and images via non-contact printing onto an automotive component prior to the vacuum formation thereof.

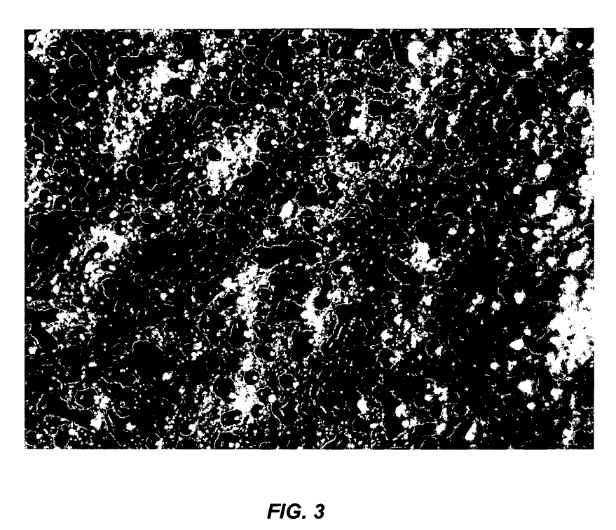

In order to prevent image distortion during flexing of the substrate during the thermoforming process described below, as illustrated in FIGS. 3 and 4, graphic pattern 10 may be formed such that only a few of the ink drops run together. Thus printing head 16 may be spaced a predetermined distance away from the surface of instrument panel 12 (i.e. 1-1.3 mm) and programmed for dispersed ink operation such that the majority of the ink drops include a predetermined degree of separation so as to allow stretching of the formed image during vacuum forming. Specifically, the provision of the separated ink drops allows stretching of the formed image during vacuum forming (discussed below) of the inter-drop zones where the thermoplastic properties of the sheet are not impaired by the presence of hard ink drops. Thus the dispersed application of discrete black (or very dark) ink drops on richly grained/textured surfaces allows stretching of the formed image during vacuum forming.

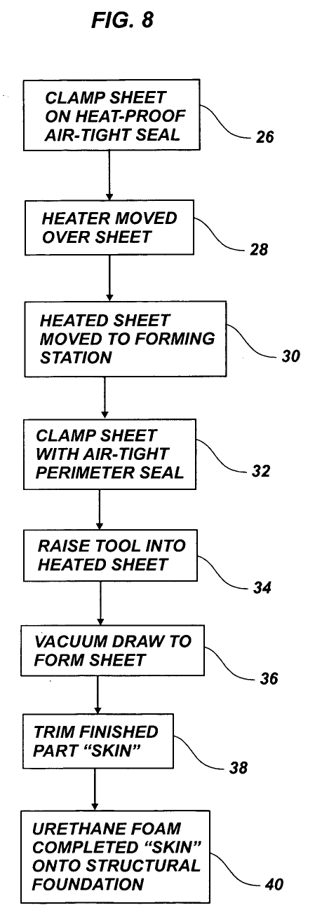

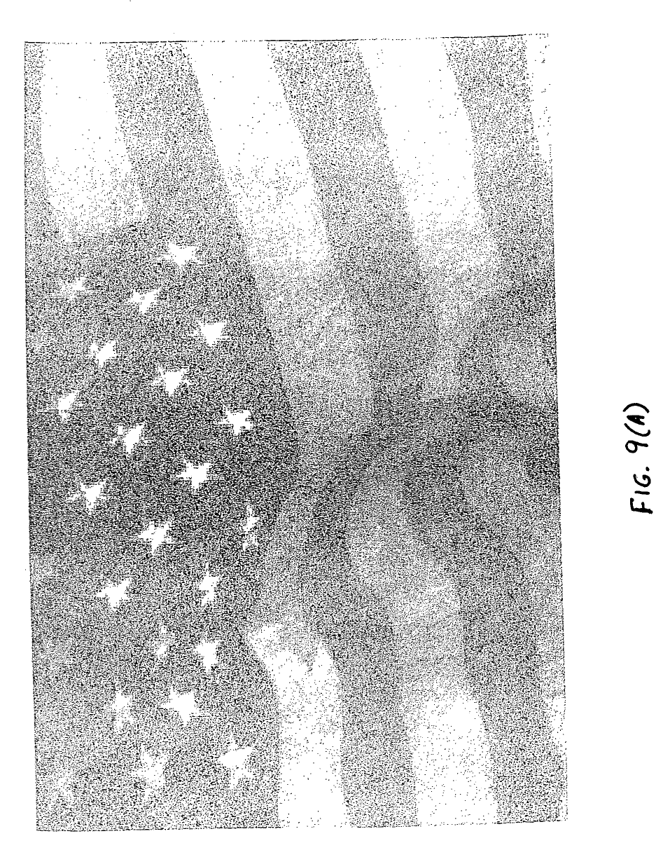

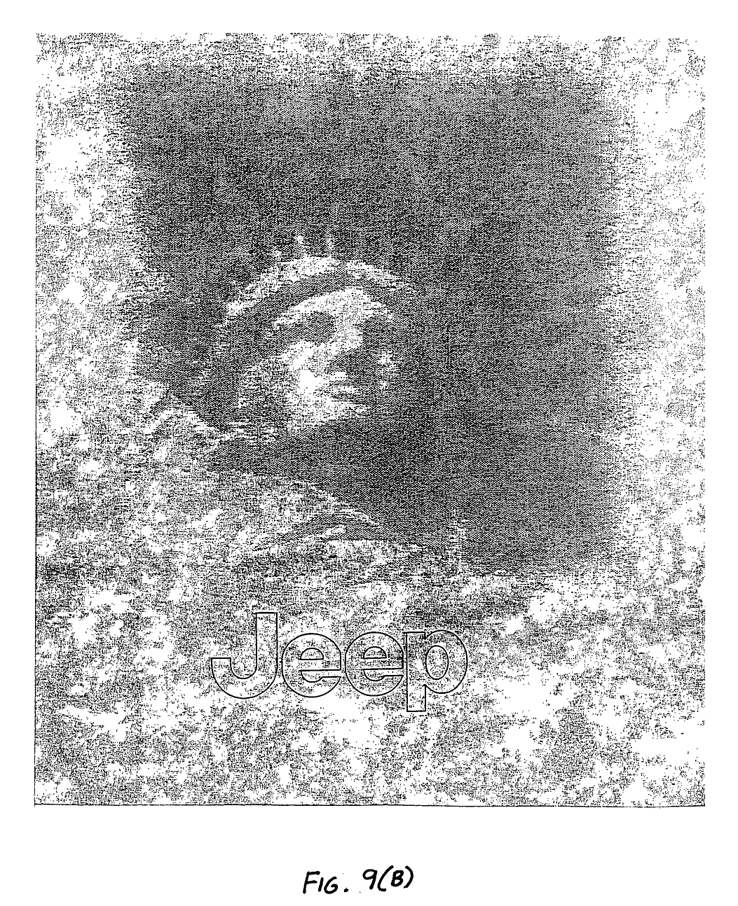

Referring to FIG. 4, a laminate 42 having graphic pattern 10 printed thereon is illustrated, prior to being formed by the sheet vacuum forming process described below. Laminate 42 may generally include a plurality of ridges/contours 44 for imparting a rough or grained appearance, as is desirable for the soft sections of today's automotive instrument panels, doors and the like. A low gloss top coat 46 in the form of a rolled on gloss control layer may be added prior to printing upon laminate 42. Laminate 42 may primarily comprise a T.P.O., T.P.U. or P.V.C. sheet 48 (pregrained and coated). The bottom layer of laminate 42 may include a back coat formulated to improve adhesion to foam in the adhesion process (see step 40 of FIG. 8) described below.

For the graphics formation method according to the present invention, since only the ink/paint is in contact with the component to be printed on and the image is created prior to vacuum forming, it becomes possible to produce an image on many different types of components and even onto surfaces with irregular three-dimensional shapes. Designs may be generated quickly and can be changed over in a matter of seconds, since the entire system may be driven primarily by a computer-based color Raster Image Processor (RIP) software. Whereas the piezoelectric ink-jet printing head is the preferred printing head for the present invention, those skilled in the art would appreciate in view of this disclosure that other ink-jet printing heads, such as the continuous ink jet printing heads, drop-on-demand, bubble jet or thermal jet printing heads, or electrostatic printer heads may be employed.

Sheet vacuum forming process 60 utilized with the graphics formation method according to the present invention will now be described in detail with reference to FIGS. 1-4 and 8.

As briefly discussed above, the graphics formation method according to the present invention includes sheet vacuum forming which involves the wrapping of a mold with heated thermoplastic (TP) sheet for forming the automotive component, and evacuating the air from between the mold and the sheet, such that atmospheric pressure pushes the sheet onto the mold, thereby stretching the sheet as required to form in three dimensions. In this context, the thermoplastic may be thermoplastic olefin (TPO), vinyl, polypropylene, or thermoplastic urethane (TPU), among other suitable materials, but preferably TPO for providing superior adhesion of ink thereto. The sheet vacuum forming process according to the present invention may advantageously use male or female (i.e. positive or negative) vacuum forming components based upon the geometric requirements of a finished part. Sheet vacuum forming may be performed by a variety of machines, from small manually operated units to fully automatic in-line production machines. For high speed and high volume production of automotive components, the present invention preferably employs fully automatic production machines.

Referring to FIG. 8, in a typical sheet vacuum forming process according to the present invention, at step 26, the TP sheet, such as sheet 48 having graphic pattern 10 printed thereon may first be clamped in place on a heat proof air-tight seal. At step 28, a heater system (not shown) may then be moved under or over the TP sheet, or vice versa, whereby the sheet is heated to its thermoforming temperature. The heater systems for use with the sheet vacuum forming process according to the present invention may include ceramic heaters or quartz emitters. The specific heater used may depend on the characteristics of a specific material being formed, and may be chosen based upon the operational characteristics and parameters discussed below.

For example, the ceramic heaters which may be utilized for the present invention consist of coiled resistance wire elements set in molded china clay, and are available in round, square or rectangular shapes, and can be flat (for maximum proximity) or curved (to provide a parabolic reflector which radiates more effectively). One key advantage of ceramic heaters is that they radiate long wavelength heat which is readily absorbed by TP sheets. Ceramic heaters also run at very high power outputs, and may be generally operated at 22.25 kw/sqm (2 kw/sqft) for vacuum forming.

A drawback of ceramic heaters is however in their high thermal mass, which requires a predetermined amount of time (i.e. 10-15 minutes) for the heaters to be warmed up to an operating temperature, and likewise decreases the response time of such heaters to energy regulation adjustments.

Accordingly, for applications requiring fast response time, quartz emitters, which include a coiled resistance wire element housed in a quartz glass tube, may alternatively be used for the sheet vacuum forming process according to the present invention. Unlike ceramic heaters, quartz emitters have a much smaller thermal mass, and thereby require minimal time for warming. Moreover, due to their medium wavelength heat, quartz emitters are much more responsive to reflectors so that a greater percentage of heat can be projected downward. A drawback of quartz emitters is that medium wavelength heat is not as readily absorbed by TP sheets as compared to the long wavelength heat of ceramic heaters.

Regardless of whether a ceramic heater or quartz emitter is utilized (or other heating elements for that matter), for the present invention, these heaters may be arranged in a reflective hood in groups or clusters which can be controlled independently so as to allow an operator to control the distribution of heat over the TP sheet, as is especially useful for complex molds.

With the required heater element in place, the typical vacuum forming cycle according to the present invention may include the following additional steps.

Referring to FIG. 8, at step 30, the TP sheet (i.e. sheet 48) may be heated to its forming temperature, and then moved into the forming station (not shown). At step 32, at the forming station, the sheet may be clamped with an air tight perimeter seal. At step 34, compressed air may be used to blow the sheet into a low bubble shape as the tool (cut to the desired surface) is raised into it. At step 36, with compressed air flow stopped, a vacuum draw may be initiated (from inside the tool) allowing air pressure to stretch and form the sheet over the tool's surface. As the sheet cools on the tool, the vacuum may be halted, and a positive air blast may be triggered to release the part. At step 38, the finished part (“skin”) may then be trimmed. The next process (step 40) in a typical instrument panel's or door's production may be the urethane foaming of this completed “skin” onto the structural foundation of an automotive component, to complete a finished part.

In the typical vacuum forming cycle discussed above, it is to be understood that the process is not limited to the particular sequence illustrated in FIG. 8, and that various changes and modifications may be effected therein by those skilled in the art without departing from the scope or spirit of the invention as defined in the. appended claims.

For the present invention, sheet thermo-formable plastic (i.e. sheet 48) may therefore be printed using the aforementioned industrial ink jet printing system by first utilizing the printing system to print, in fogged (i.e. not fully wetted-out) patterns, a pattern onto the TP sheet, and thereafter, utilizing the aforementioned sheet vacuum forming process to form the printed-upon sheet into the required three-dimensional shape. After being printed and formed, the pre-finished sheet may thereafter be trimmed and bonded (using a foam product) to a structural foundation to complete the instrument panel, door and the like.

By integrating the aforementioned sheet vacuum forming and industrial ink jet printing methods, the graphics formation method according to the present invention thereby enables high volume and high speed production of durable high quality large area graphics patterns on grained three dimensional components, such as the “soft” sections of automotive instrument panels, doors and the like.

The present invention thus provides a graphics formation method which provides unlimited subtlety in automotive interior graphics, such that instrument panel or door coloration and gloss is tightly limited to prevent reflections in the windshield and distractions for a driver. The ability of the graphics formation method according to the present invention to “fog” very low densities of ink/paint droplets, in a very controlled manner, allows for unlimited variable image intensity within a predetermined range including moderate to faint graphics. This unlimited intensity allows for the most desirable effect in an application (i.e. simulated water marks or very subtle “ghost images” with minimal intensity and low gloss). Due to the subtlety of the images created, for an instrument panel or door manufactured by the graphics formation method of the present invention, a driver or passenger would not be overly distracted by such images, and the reflected glare in the windshield coming from the printed-upon surfaces would be extremely low.

By using the aforementioned industrial ink jet printing method of the present invention, the invention enables the printed upon sheets to be vacuum formed without the hard durable ink/paint cracking or delaminating. As discussed above, the planned patterns according to the present invention include a very tightly controlled array of drops on the thermoformable sheet surface (i.e. sheet 48), and include a predetermined separation therebetween so as to permit the stretching required when vacuum forming complex three dimensional surfaces.

The aforedescribed graphics formation method of the present invention may be applied to vacuum formed compact sheet skins (i.e. single layer thermoformable plastic sheets such as poly vinyl chloride or thermo plastic olifin or thermo plastic urethane, or thermo plastic elastomer), which may then be urethane foamed (i.e. so as to produce a soft layer/feel) to a structural foundation (i.e. the structural component below the finished surface on urethane foamed parts).

The aforedescribed graphics formation method of the present invention, may also be applied to vacuum wrapped laminate instrument panels, doors and the like. In a particular construction, a one, two or more layered thermo plastic sheet may be heated and vacuum wrapped over the structural foundation (with a glue securing it). For the vacuum wrapped laminate, a separate urethane foaming process is not used. Thus, the parts would not have a soft feel in the case of the single layer vacuum wrapped construction, but would typically have a somewhat soft feel in the case of multi-layered wrapping materials (where one layer is of a thermoplastic foamed material prior to wrapping).

Graphic pattern 10 according to the present invention may therefore be applicable to the soft sections of a variety of automotive grained or textured components, such as automotive dashboard parts which include the automotive instrument panel itself (the main plastic component, running the full width of the vehicle which is grained or textured), doors and the like. Graphic pattern 10 may also be applicable to the soft flat as well as the contoured (three-dimensional) or grained surfaces of the instrument panels, doors and the like.

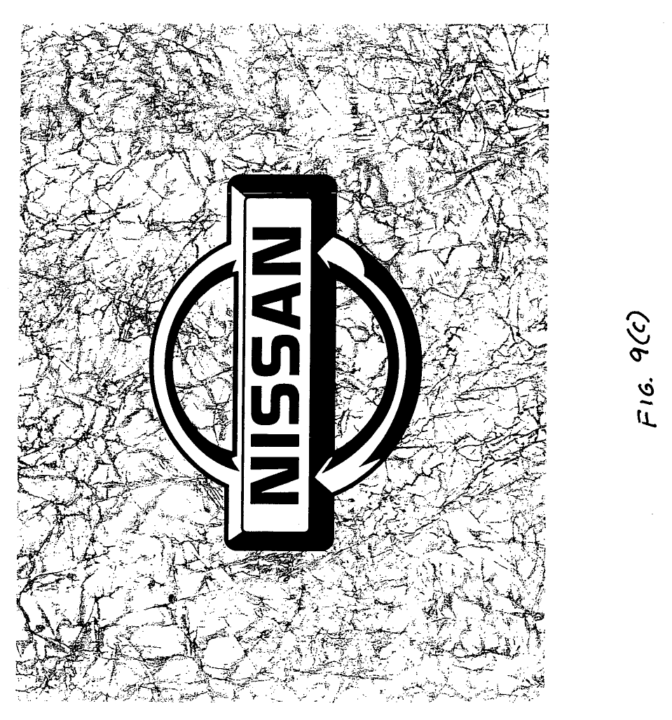

Exemplary applications of the aforedescribed graphics formation method will now be described in detail with reference to FIGS. 2 and 9(a)-9(c).

Specifically, as illustrated in FIGS. 2 and 9(a)-9(c), the graphics formation method according to the present invention may be utilized to produce an unlimited variety of automotive interior graphics for applications on the soft sections of automotive instrument panels, doors and the like. Since the graphics formation method of the present invention allows for controlled fogging of very low densities of ink/paint droplets, the intensity and variety of images produced may be varied as needed for applications on different sections of automotive instrument panels, doors and the like.

For exemplary applications of the graphics formation method of the present invention, the present invention further provides a method of associating, selecting and applying a predetermined category of images onto the soft sections of automotive instrument panels, doors and the like.

Specifically, graphic pattern 10 according to the present invention may be selected for application onto the soft sections of automotive instrument panels, doors and the like based upon factors such as the general territory for an automobile (i.e. west coast, mid-west, east coast etc.), the general category of an automobile (i.e. sports car, sedan, SUV etc.), the targeted consumer category (i.e. middle-aged, elderly etc.) and a host of additional factors. These factors may then be associated with an automobile such that the graphic pattern printed therein is selected based upon factors such as the general sales territory, the category of automobile, and the targeted consumer category.

Based upon the aforementioned factors and considerations, referring to FIG. 9(a), an exemplary application of the aforementioned association, selection and application method may include the printing of an automobile emblem (i.e. JEEP for FIGS. 9(b) and NISSAN for 9(c)) onto the soft sections of automotive instrument panels, doors and the like. Other similar applications of the aforementioned association, selection and application method may include the application of leaves for example, for automobiles sold in states such as New England, mountains for states such as Colorado, beach or surf images for states such as Virginia or California, and other graphic patterns such as scenic images of cottages, water, birds etc.

To summarize, the present invention thus provides a method and apparatus for thermoforming of ink jet printed media for decoration of automotive interior components, and further provides a method of associating, selecting and applying a graphic pattern onto a thermoformed automotive interior component.

Although particular embodiments of the invention have been described in detail herein with reference to the accompanying drawings, it is to be understood that the invention is not limited to those particular embodiments, and that various changes and modifications may be effected therein by one skilled in the art without departing from the scope or spirit of the invention as defined in the appended claims.

1. A method of thermoforming of ink jet printed media for decoration of soft grained automotive interior components, excluding hard trim plates, said method comprising:
controlling an ink jet printer head for dispersed ink application onto a thermoplastic sheet;
selecting a predetermined graphic pattern for application onto said thermoplastic sheet;
applying said predetermined graphic pattern onto said thermoplastic sheet by means of said ink jet printer head to thereby form a decorated thermoplastic sheet, said predetermined graphic pattern including a dispersed ink pattern which includes a plurality of ink drops having spacing between adjacent ink drops, said spacing defining a plurality of inter-ink drop zones;
vacuum forming said decorated thermoplastic sheet into a desired shape;
stretching said decorated thermoplastic sheet during said vacuum forming such that during said stretching, said graphic pattern is stretched due to stretching of said inter-ink drop zones; and
applying said vacuum formed decorated thermoplastic sheet to an automotive interior component structural foundation using a curing foam.

2. A method according to claim 1, wherein said automotive interior component is one of an instrument panel and a door set having said vacuum formed decorated thermoplastic sheet applied to the structural foundation thereof for thereby forming a soft grained decorated automotive interior component.

3. A method according to claim 1, wherein said graphic pattern on said vacuum formed decorated thermoplastic sheet is applicable to flat, contoured and grained surfaces of said thermoplastic sheet.

4. A method according to claim 1, wherein said ink jet printer head is a piezoelectric printer head.

5. A method according to claim 1, further comprising utilizing low gloss ultraviolet cured inks with said ink jet printer head such that said graphic pattern meets automotive performance criteria without a protective top clear coat.

6. A method according to claim 1, wherein said graphic pattern includes a plurality of subtle changes in a surface tone of said thermoplastic sheet by using low contrast ink and plastic colors in faint patterns.

7. A method according to claim 1, wherein said vacuum forming is negative vacuum forming.

8. A method of thermoforming of ink jet printed media for decoration of automotive interior components, said method comprising:
controlling an ink jet printer head for dispersed ink application onto a thermoplastic sheet;
selecting a predetermined graphic pattern for application onto said thermoplastic sheet;
applying said predetermined graphic pattern onto said thermoplastic sheet by means of said ink jet printer head to thereby form a decorated thermoplastic sheet, said predetermined graphic pattern including a dispersed ink pattern which includes a plurality of ink drops having spacing therebetween, said spacing defining a plurality of inter-ink drop zones;
vacuum forming said decorated thermoplastic sheet into a desired shape; and
applying said vacuum formed decorated thermoplastic sheet to an automotive interior component structural foundation.

9. A method according to claim 8, further comprising stretching said decorated thermoplastic sheet during said vacuum forming such that during said stretching, said graphic pattern is stretched due to stretching of said inter-ink drop zones.

10. A method according to claim 8, wherein said automotive interior component is one of an instrument panel and a door set having said vacuum formed decorated thermoplastic sheet applied to the structural foundation thereof for thereby forming a decorated automotive interior component.

11. A method according to claim 8, wherein said graphic pattern on said vacuum formed decorated thermoplastic sheet is applicable to flat, contoured and grained surfaces of said thermoplastic sheet.

12. A method according to claim 8, wherein said ink jet printer head is a piezoelectric printer head.

13. A method according to claim 8, further comprising utilizing ultraviolet cured inks with said ink jet printer head such that said graphic pattern meets automotive performance criteria, without a protective top clear coat.

14. A method according to claim 8, wherein said selected graphic pattern is applied to soft sections of said automotive interior component.

15. A method according to claim 8, wherein said graphic pattern includes a plurality of subtle changes in a surface tone of said thermoplastic sheet by using low contrast ink and plastic colors in faint patterns.

16. A method according to claim 8, wherein said vacuum forming is negative vacuum forming.

17. An apparatus for thermoforming of ink jet printed media for decoration of automotive interior components, said apparatus comprising:
a controller for controlling an ink jet printer head for dispersed ink application onto a thermoplastic sheet;
a predetermined graphic pattern being applied onto said thermoplastic sheet by means of said ink jet printer head to thereby form a decorated thermoplastic sheet, said predetermined graphic pattern including a dispersed ink pattern which includes a plurality of ink drops having spacing therebetween, said spacing defining inter-ink drop zones; and
a vacuum forming apparatus for forming said thermoplastic sheet into a desired shape.

18. An apparatus according to claim 17, wherein said thermoplastic sheet is stretched during said vacuum forming such that during said stretching, said graphic pattern is stretched due to stretching of said inter-ink drop zones.

19. An apparatus according to claim 17, wherein said vacuum formed decorated thermoplastic sheet is applied to an automotive interior component structural foundation, said automotive interior component is one of an instrument panel and a door set.

20. An apparatus according to claim 17, wherein said graphic pattern on said vacuum formed decorated thermoplastic sheet is applicable to flat, contoured and grained surfaces of said thermoplastic sheet.

21. An apparatus according to claim 17, wherein said ink jet printer head is a piezoelectric printer head.

22. An apparatus according to claim 17, wherein said ink jet printer head utilizes ultraviolet cured inks such that said graphic pattern meets automotive performance criteria, without a protective top clear coat.

23. An apparatus according to claim 17, wherein said selected graphic pattern is applied to soft sections of an automotive interior component.

24. An apparatus according to claim 17, wherein said graphic pattern includes a plurality of subtle changes in a surface tone of said thermoplastic sheet by using low contrast ink and plastic colors in faint patterns.

25. An apparatus according to claim 17, wherein said vacuum forming apparatus is a negative vacuum forming apparatus.

26. A method of associating, selecting and applying a graphic pattern onto a thermoformed automotive interior component, said method comprising:
associating a graphic pattern with one of a general territory of sale of an automobile, a general category of the automobile, and a targeted consumer category related to the automobile;
selecting an associated graphic pattern for application onto a thermoplastic sheet for forming said automotive interior component;
controlling an ink jet printer head for dispersed ink application onto said thermoplastic sheet;
applying said predetermined graphic pattern onto said thermoplastic sheet by means of said ink jet printer head to thereby form a decorated thermoplastic sheet, said predetermined graphic pattern including a dispersed ink pattern which includes a plurality of ink drops having spacing therebetween, said spacing defining a plurality of inter-ink drop zones;
vacuum forming said decorated thermoplastic sheet into a desired shape; and
applying said vacuum formed decorated thermoplastic sheet to an automotive interior component structural foundation.

27. A method according to claim 26, further comprising stretching said decorated thermoplastic sheet during said vacuum forming such that during said stretching, said graphic pattern is stretched due to stretching of said inter-ink drop zones.

28. A method according to claim 26, wherein said automotive interior component is one of an instrument panel and a door set having said vacuum formed decorated thermoplastic sheet applied to the structural foundation thereof for thereby forming a decorated automotive interior component.

29. A method according to claim 26, wherein said graphic pattern on said vacuum formed decorated thermoplastic sheet is applicable to flat, contoured and grained surfaces of said thermoplastic sheet.

30. A method according to claim 26, wherein said ink jet printer head is a piezoelectric printer head.

31. A method according to claim 26, further comprising utilizing ultraviolet cured inks with said ink jet printer head such that said graphic pattern meets automotive performance criteria, without a protective top clear coat.

32. A method according to claim 26, wherein said selected graphic pattern is applied to soft grained sections of said automotive interior component.

33. A method according to claim 26, wherein said graphic pattern simulates shading for imitating three-dimensional details of a surface of said automotive interior component.

34. A method according to claim 26, wherein said graphic pattern includes a plurality of subtle changes in a surface tone of said thermoplastic sheet by using low contrast ink and plastic colors in faint patterns.

35. A method according to claim 26, wherein said vacuum forming is negative vacuum forming.
